(19) United States
(12) Patent Application Publication
(10) Pub. No.: US 2023/0377853 A1
(43) Pub. Date: Nov. 23, 2023

(54) PLASMA SYSTEMS AND PROCESSES WITH PULSED MAGNETIC FIELD

(71) Applicant: TOKYO ELectron Limited, Tokyo (JP)

(72) Inventors: Ya-Ming Chen, Austin, TX (US); Shyam Sridhar, Austin, TX (US); Peter Lowell George Ventzek, Austin, TX (US); Alok Ranjan, Austin, TX (US); Mitsunori Ohata, Taiwa-cho (JP)

(21) Appl. No.: 17/841,957

(22) Filed: Jun. 16, 2022

Related U.S. Application Data
(60) Provisional application No. 63/344,597, filed on May 22, 2022.

(51) Int. Cl. H01J 37/32; H01L 21/3213

(52) U.S. Cl. CPC H01J 37/32669; H01J 37/32146; H01L 21/32139; H01L 21/32137; H01J 2237/334

(57) ABSTRACT

A plasma etching system for a substrate including: a plasma processing chamber; a substrate holder disposed in the plasma processing chamber; a RF power source configured to generate a plasma in the plasma processing chamber; a set of electromagnets configured to apply a magnetic field in the processing chamber, the magnetic field of the set of the electromagnets being independent from a magnetic field generated by the RF power source; and a microprocessor coupled to the RF power source and the set of electromagnets, the microprocessor including a non-volatile memory having a program including instructions to: power the RF power source and generate the plasma in the processing chamber to etch the substrate; and provide a power pulse train to the set of electromagnets and generate the magnetic field that is pulsed, in the plasma processing chamber.

### CROSS-REFERENCE TO RELATED APPLICATIONS

This application claims the benefit of U.S. Provisional Application No. 63/344,597, filed on May 22, 2022, which application is hereby incorporated herein by reference.

### TECHNICAL FIELD

The present invention relates generally to a system and method of processing a substrate and, in particular embodiments, to plasma systems and processes with pulsed magnetic field.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the processing steps used to form the constituent structures of semiconductor devices are performed using plasma processes. Plasma processing techniques include chemical dry etching (CDE) (e.g., plasma ashing), physical or sputter etching, reactive ion etching (RIE), and plasma-enhanced chemical vapor deposition (PECVD).

Driven by an insatiable demand for low cost electronics with high functionality, the minimum feature sizes have been shrunk to reduce cost by roughly doubling the component packing density at each successive technology node. Innovations in patterning such as immersion photolithography, multiple patterning, and 13.5 nm wavelength extreme ultraviolet (EUV) optical systems have brought critical feature sizes down close to ten nanometers. Concurrently, unconventional materials such as organics, ferroelectrics, and chalcogenides are being increasingly used in products. This scenario poses a challenge for plasma technology to provide processes for patterning features with accuracy, precision, and profile control, often at atomic scale dimensions. Meeting this challenge along with the uniformity and repeatability needed for high volume IC manufacturing requires further innovations.

### SUMMARY

In accordance with an embodiment of the present invention, a plasma etching system for a substrate including: a plasma processing chamber; a substrate holder disposed in the plasma processing chamber; a RF power source configured to generate a plasma in the plasma processing chamber; a set of electromagnets configured to apply a magnetic field in the processing chamber, the magnetic field of the set of the electromagnets being independent from a magnetic field generated by the RF power source; and a microprocessor coupled to the RF power source and the set of electromagnets, the microprocessor including a non-volatile memory having a program including instructions to: power the RF power source and generate the plasma in the processing chamber to etch the substrate; and provide a power pulse train to the set of electromagnets and generate the magnetic field that is pulsed, in the plasma processing chamber.

In accordance with an embodiment of the present invention, a method of processing a substrate that includes: loading the substrate in a plasma processing chamber, the substrate including a patterned hard mask layer and an underlying layer, the processing chamber including a RF power source and a set of electromagnets; flowing a process gas into the plasma processing chamber; generating a plasma from the process gas in the plasma processing chamber by powering the RF power source; providing a power pulse train to the set of electromagnets to generate a magnetic field in the plasma processing chamber, the magnetic field being stronger near an edge of the plasma than near a center of the plasma; and while providing the power pulse train to the set of electromagnets, exposing the substrate to the plasma and etching the underlying layer selectively to the hard mask layer.

In accordance with an embodiment of the present invention, a method of processing a substrate that includes: loading the substrate in a plasma processing chamber, the substrate including a patterned hard mask layer and an underlying layer, the processing chamber including a RF power source and a set of electromagnets; flowing a process gas into the plasma processing chamber; generating a plasma from the process gas in the plasma processing chamber by powering the RF power source; exposing the substrate to the plasma and etching the underlying layer selectively to the hard mask layer, where an etch rate is greater at near an edge region of the substrate than at a central region of the substrate; and providing a power pulse train to the set of electromagnets to generate a magnetic field in the plasma processing chamber, the magnetic field reducing the difference in the etch rate between near the edge region and the central region.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example plasma processing system having a set of electromagnets in accordance with various embodiments;

FIG. 2 illustrates a schematic of plasma species in a conventional plasma processing chamber;

FIG. 3 illustrates a schematic of plasma species in a plasma processing chamber under a magnetic field applied by a set of electromagnets in accordance with various embodiments;

FIGS. 4A and 4B illustrate example time diagrams for source power, radical concentration of a plasma, and an electron temperature in the absence of an additional magnetic field, wherein FIG. 4A illustrates a case of continuous-wave (CW) operation, and FIG. 4B illustrates a case of pulsed-power operation;

FIGS. 5A and 5B illustrate example time diagrams for source power, radical concentration of a plasma, an electron temperature, and an additional pulsed magnetic field in accordance with various embodiments, wherein FIG. 5A illustrates a case of continuous-wave (CW) operation, and FIG. 5B illustrates a case of pulsed-power operation;

FIGS. 6A-6D illustrate time diagrams for pulsed source power and pulsed additional magnetic field in other embodiments, wherein FIG. 6A illustrates a case of complete synchronization, FIG. 6B illustrates a case of overlapping, FIG. 6C illustrates a case of multiple pulsing per source power cycle, and FIG. 6D illustrates a case of triangle wave for the pulsed additional magnetic field;

FIGS. 7A-7B illustrate an example electron distribution in the absence of an additional magnetic field, wherein FIG. 7A illustrates a schematic of electrons of a plasma in a plasma processing chamber, and wherein FIG. 7B illustrates the electron distribution as a function of radial position relative to the substrate;

FIGS. 8A-8B illustrate an example electron distribution with an additional magnetic field in accordance with one embodiment, wherein FIG. 8A illustrates a schematic of electrons of a plasma in a plasma processing chamber, and wherein FIG. 8B illustrates the electron distribution as a function of radial position relative to the substrate;

FIGS. 9A-9B illustrate an example electron distribution with an additional magnetic field in accordance with another embodiment, wherein FIG. 9A illustrates a schematic of electrons of a plasma in a plasma processing chamber, and wherein FIG. 9B illustrates the electron distribution as a function of radial position relative to the substrate;

FIG. 10 illustrates a cross sectional view of an example substrate after a plasma etch with local bowing issues near the edge region of the substrate;

FIG. 11 illustrates a cross sectional view of an example substrate after a plasma etch that uses an additional magnetic field in accordance with various embodiments, where a uniform etch profile across the substrate is enabled; and

FIG. 12 illustrates an example process flow diagrams in accordance with various embodiments.

### DETAILED DESCRIPTION OF ILLUSTRATIVE EMBODIMENTS

This application relates to a method of processing a substrate, more particularly to modulation of local density of plasma species using an applied magnetic field. Plasma etching often requires highly directional etching, and balancing etch rate, selectivity, and uniformity sufficiently can be challenging. Etching of silicon (Si) in halogenated plasmas, for example, may rely on sufficient passivation provided by etch byproducts to realize damage-free, vertical etch profiles. However, serious loading and clogging can happen if the amount of radical and etch byproduct in the plasma is not optimized. A non-uniform plasma makes it difficult to maintain the optimized balance of these species. Wafer loading and non-uniformity are common issues for plasma processing, due to the non-uniformity of species such as radicals and etch byproducts. For instance, during a gate etching process, due to the non-uniformity of passivating agents across the substrate, bowed profiles can be seen at the edge of the substrate while the etch profile at the center is vertical. Therefore, a new plasma technique that can provide a better uniformity for a highly directional plasma etching may be desired. Embodiments of the present application disclose methods of using pulsed magnetic field to modulate plasma parameters, such as electron temperature and electron loss rate for uniformity improvement. Specifically, in various embodiments, pulsed magnetic field synchronized/asynchronized with pulsed RF source power is applied to modulate the local dissociation rate of radicals and etch by-products as to tune the local density of polymerizing species for passivation.

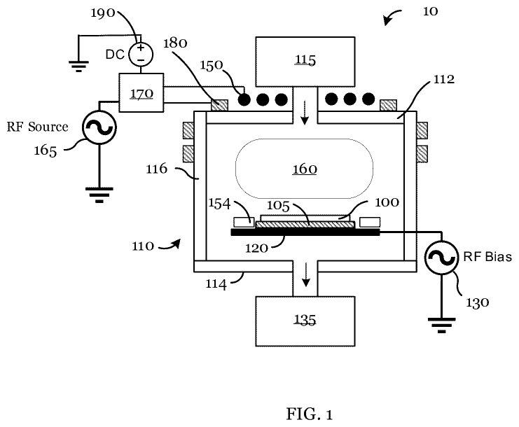

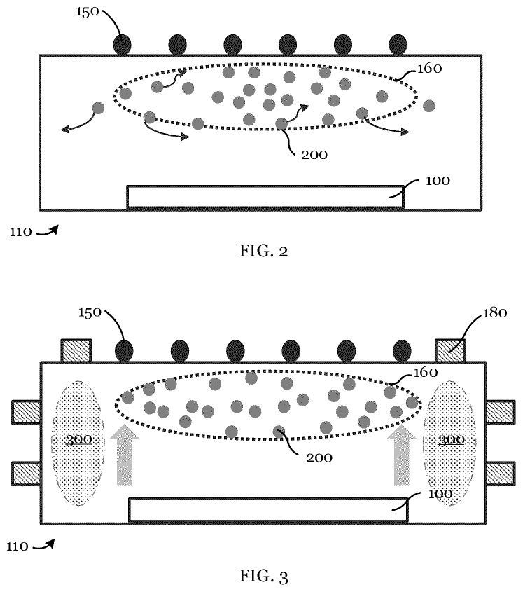

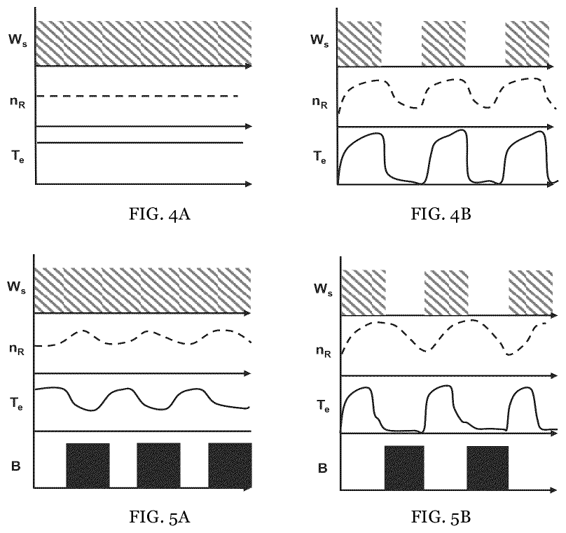

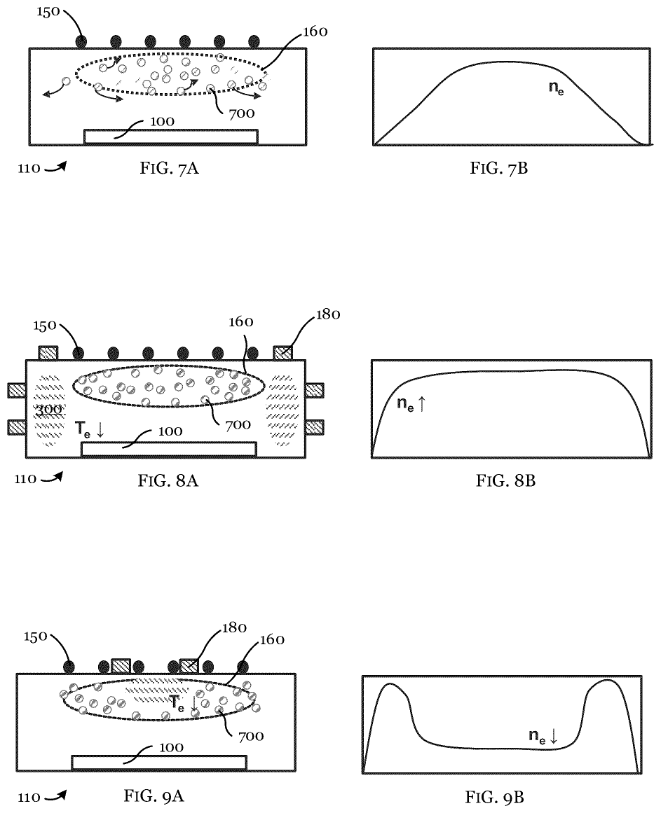

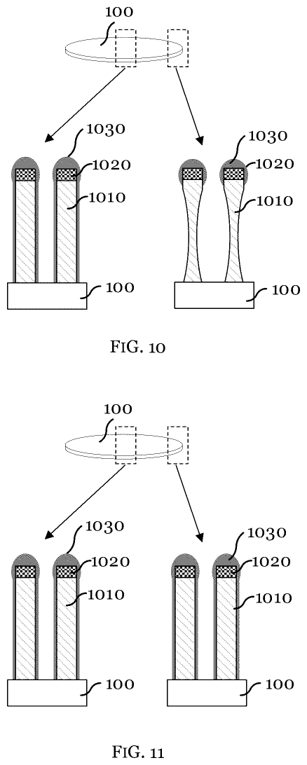

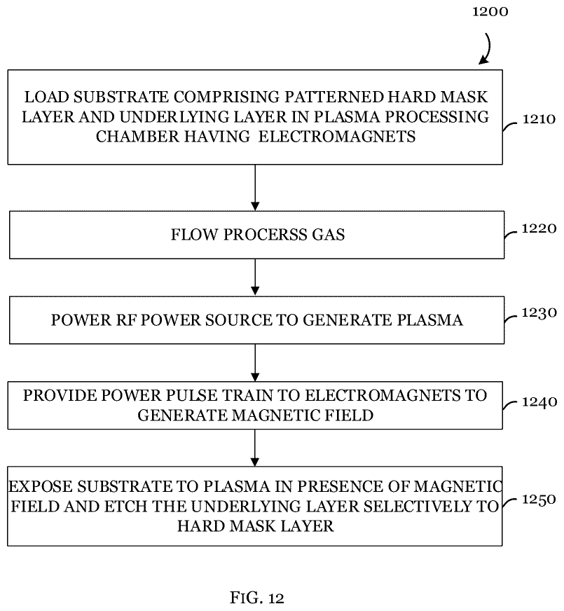

In the following, an example plasma processing system incorporating a set of electromagnets is first described referring to FIG. 1. The effect of pulsing an additional magnetic field using the set of electromagnets is then described referring to FIGS. 2 and 3. Various modes for source power and magnetic field pulsing are explained referring to FIGS. 4A-4B, 5A-5B, and 6A-6D. Subsequently, the effect of the additional magnetic field on electron distributions of the plasma is described referring to FIGS. 7A-7B, 8A-8B, and 9A-9B. Suppression of bowing as a result of improving the uniformity of plasma through the additional magnetic field is illustrated in FIGS. 10 and 11. Example process flow diagrams are illustrated in FIG. 12. All figures in this disclosure are drawn for illustration purpose only and not to scale, including the aspect ratios of features.

FIG. 1 illustrates an example plasma processing system 10 having a set of electromagnets in accordance with various embodiments.

As illustrated in FIG. 1, the plasma processing system 10 comprises a plasma processing chamber 110, and a substrate 100 may be placed on a substrate holder 105. In various embodiments, the substrate 100 may be a part of, or including, a semiconductor device, and may have undergone a number of steps of processing following, for example, a conventional process. The substrate 100 accordingly may comprise layers of semiconductors useful in various microelectronics. For example, the semiconductor structure may comprise the substrate 100 in which various device regions are formed.

In one or more embodiments, the substrate 100 may be a silicon wafer, or a silicon-on-insulator (SOI) wafer. In certain embodiments, the substrate 100 may comprise a silicon germanium wafer, silicon carbide wafer, gallium arsenide wafer, gallium nitride wafer and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device.

In various embodiments, the plasma processing system 10 may further comprise a focus ring 154 positioned over the bottom electrode 120 to surround the substrate 100. The focus ring 154 may advantageously maintain and extend the uniformity of the plasma 160 to achieve process consistency at the edge of the substrate 100. In various embodiments, the focus ring 154 may have a width of a few cm. In various embodiments, there may be a gap for mechanical clearance between the circumference of the substrate 100 and the focus ring 154. In certain embodiments, the gap may be hundreds of microns to a few mm. In various embodiments, the focus ring 154 may comprise a dielectric material with a desired dielectric constant. In certain embodiments, the focus ring 154 may comprise silicon. Some examples of silicon-based focus ring may comprise silicon, silicon oxide, doped silicon (e.g., boron-doped, nitrogen-doped, and phosphorous-doped), or silicon carbide. Alternatively, in some embodiments, the focus ring may comprise a carbon-based material. In one or more embodiments, the focus ring 154 may comprise a metal oxide, such as aluminum oxide and zirconium oxide.

A process gas may be introduced into the plasma processing chamber 110 by a gas delivery system 115. The gas delivery system 115 may comprise multiple gas flow controllers to control the flow of multiple gases into the plasma processing chamber 110. In some embodiments, optional center/edge splitters may be used to independently adjust the gas flow rates at the center and edge of the substrate 100. Further, in one embodiment, the gas delivery system 115 may have a special showerhead configuration positioned at the top of the plasma processing chamber 110. For example, the gas delivery system 115 may have a showerhead configuration, covering the entirety of the substrate 100, including a plurality of appropriately spaced gas inlets. Alternatively, gas may be introduced through dedicated gas inlets of any other suitable configuration. The plasma processing chamber 110 may further be equipped with one or more sensors such as pressure monitors, gas flow monitors, and/or gas species density monitors. The sensors may be integrated as a part of the gas delivery system 115 in various embodiments.

In FIG. 1, the plasma processing chamber 110 is a vacuum chamber and may be evacuated using one or more vacuum pumps 135, such as a single stage pumping system or a multistage pumping system (e.g. a mechanical roughing pump combined with one or more turbomolecular pumps). In order to promote even gas flow during plasma processing, gas may be removed from more than one gas outlet or location in the plasma processing chamber 110 (e.g., on opposite sides of the substrate 100).

In various embodiments, the substrate holder 105 may be integrated with, or a part of, a chuck (e.g., a circular electrostatic chuck (ESC)) positioned near the bottom of the plasma processing chamber 110, and connected to a bottom electrode 120. The surface of the chuck or the substrate holder 105 may be coated with a conductive material (e.g., a carbon-based or metal-nitride based coating). The substrate 100 may be optionally maintained at a desired temperature using a temperature sensor and a heating element connected to a temperature controller (not shown). In certain embodiments, the temperature sensor may comprise a thermocouple, a resistance temperature detector (RTD), a thermistor, or a semiconductor based integrated circuit. The heating element may for example comprise a resistive heater in one embodiment. In addition, there may be a cooling element such as a liquid cooling system coupled to the temperature controller. The bottom electrode 120 may be connected to a RF bias power sources 130.

Further in FIG. 1, a top electrode 150 may be a conductive helical coil electrode located outside the plasma processing chamber 110, positioned above a top plate 112. The top electrode 150 may be connected to RF power source 165 via a controller 170. The top plate 112, a bottom plate 114, and a side wall 116 may be conductive and electrically connected to the system ground (a reference potential).

A typical frequency for the RF source power can range from about 0.1 MHz to about 6 GHz, and can be 13.56 MHz. While only one RF power source is illustrates in FIG. 1, more than one RF power sources may be used in various embodiments, for example, to provide a low frequency RF power and a high frequency RF power at the same time. The plasma 160 may be generated and sustained by continuous wave (CW) or pulsed RF power.

In various embodiments, a RF pulsing at a kHz range may be used to power the plasma 160. Using the RF pulsing may help generating high energetic ions (>keV) in the plasma 160 for the plasma etch process, while reducing a charging effect. In certain embodiments, a moderate duty ratio between 40% to 80% may be used. In one embodiment, a bias power of 18 kW may be pulsed at a frequency of 5 kHz with a duty ratio of 60%.

The plasma processing system 10 is particularly characterized by a set of electromagnets 180 configured to apply an additional magnetic field to the plasma 160, where the additional magnetic field is independent from a magnetic field already generated by the RF power source 165 in the plasma 160. In various embodiments, the set of electromagnets 180 may be connected to a DC power source 190 via the controller 170. In other embodiments, a RF power source may be used to power the set of electromagnets 180. In FIG. 1, 6 electromagnets are illustrated, but they are for example only, and any number of electromagnets may be used. In certain embodiments, some of the electromagnets may be positioned on the top plate 112 and the side wall 116. In particular, those electromagnets may be positioned concentrically near above the edge of the substrate holder 105 rather than the center thereof. As further described below, the position of the electromagnets may be selected in consideration of an ideal arrangement to locally apply a magnetic field, rather than establishing a magnetic field uniform in the plasma processing chamber 110. This is because the methods in this disclosure are configured to modify the local density of plasma species, thereby reducing or eliminating non-uniformity of the plasma species across in the plasma processing chamber.

In various embodiments, the controller 170 is coupled to both the top electrode 150 and the set of electromagnets 180 to advantageously enable the synchronous or asynchronous operations of controlling the RF power and the additional magnetic field. With the capability of the controller 170 to control these two parameters simultaneously, the uniformity of the plasma 160 may be finely tuned to achieve the desired etch performance.

The configurations of the plasma etching system described above is for example only. In alternative embodiments, various alternative configurations may be used for a plasma processing system that incorporates a set of electromagnets. For example, the plasma processing system may be a resonator such as a helical resonator. Further, microwave plasma (MW) or other suitable systems may be used. In various embodiments, the RF power, chamber pressure, substrate temperature, gas flow rates and other plasma process parameters may be selected in accordance with the respective process recipe.

In addition, embodiments of the present invention may be also applied to remote plasma systems as well as batch systems. For example, the substrate holder may be able to support a plurality of wafers that are spun around a central axis as they pass through different plasma zones. Accordingly, it is possible to have multiple plasma zones, for example, including a metal-containing plasma zone, metal-free plasma zone, and plasma-free zone (e.g., a purge zone).

FIG. 2 illustrates a schematic of plasma species 200 in a conventional plasma processing chamber 110. FIG. 3 illustrates a schematic of plasma species 200 in a plasma processing chamber 110 under a magnetic field applied by a set of electromagnets in accordance with various embodiments.

In FIGS. 2 and 3, simplified schematics of a plasma processing chamber 110 with a conventional design and with a set of electromagnets 180 in various embodiments are illustrated and compared so as to describe the effect of pulsing an additional magnetic field. Wafer loading and non-uniformity are common issues for plasma processing, due to the non-uniformity of radicals and etch byproducts. In FIG. 2, the non-uniformity of a plasma 160 is illustrated by uneven distribution of the plasma species 200, where the concentration of the plasma species 200 is higher near the center of the plasma 160 than near the edge of the plasmas 160. In one or more embodiments, the plasma species 200 may comprise passivating agents that can provide passivation on surface to avoid excessive etching by etchant species. In this scenario, because the plasma 160 is positioned above the substrate 100 and the edge of the plasma 160 may generally correspond to the edge of the substrate 100, the lower concentration of the passivation agents near the edge of the plasmas 160 may lead to non-uniform etch profile such as greater bowing issues at the edge of the substrate 100 (e.g., FIG. 10).

To overcome this non-uniformity issue of a plasma, in accordance with various embodiments, an additional magnetic field may be applied locally in the plasma processing chamber 110, as illustrated in FIG. 3. Using the set of electromagnets 180, one or more additional magnetic fields 300 may be applied. In FIG. 3, the additional magnetic field 300 is applied in a ring shape that concentrically surrounds the edge of the plasma 160. The cross sectional view of FIG. 3 therefore illustrates two regions of the additional magnetic field 300 near the sidewalls of the plasma processing chamber 110. In this disclosure, the term of the “additional” magnetic field may be used to indicate that the magnetic field applied by the electromagnets is independent from a magnetic field already generated by the RF power source used to generate the plasma 160.

Although not wishing to be limited by any theory, with a magnetic field applied, the electron temperature of the plasma may decreased due to electron trapping in the magnetic field, resulting in lower electron mobility. Accordingly, when the additional magnetic field is locally applied, for example, only at the edge region of the plasma, it may locally change the plasma parameters including the electron mobility particularly in the edge region. Lowering the electron temperature and mobility may lead to an increase in radical species, which in turn may improve the concentration of the passivating agents locally. This may be because plasma polymerization (i.e., the amount of polymerizing component in the plasma such as the passivating agents) is highly dependent on the dissociation and recombination of radicals, and locally adding a magnetic field to the plasma 160 may enable a local increase in the radicals and consequently making the plasma condition more polymerizing where the magnetic field is added. Due to the effect of the additional magnetic field, in FIG. 3, the uniformity of distribution of the plasma species 200 may be improved compared to FIG. 2.

FIGS. 4A and 4B illustrate example time diagrams for source power (Wₛ), radical concentration of a plasma (n_{R}), and an electron temperature (Tₑ) in the absence of an additional magnetic field. FIGS. 5A and 5B illustrate example time diagrams for source power (Wₛ), radical concentration of a plasma (n_{R}), an electron temperature (Tₑ), and an additional pulsed magnetic field (B) in accordance with various embodiments. Although not specifically described below, the magnetic field is assumed to be applied locally, rather than uniformly in the plasma processing chamber, to enable a local modulation of the plasma species.

In various embodiments, an additional magnetic field may be applied as a pulse train to modulate the local density of plasma species. In addition, the pulsing of the magnetic field may be performed independently from the powering of the plasma or in synchronization.

Referring to FIGS. 4A and 5A, a case of continuous-wave (CW) operation is described. In this case, a continuous wave power is provided to generate and sustain a plasma. Accordingly, the radical concentration of the plasma (n_{R}) and the electron temperature (Tₑ) may be constant as illustrated in FIG. 4A. A pulse train may be applied to generate the additional magnetic field as illustrated in FIG. 5A, resulting in a periodical decrease in Tₑ and a corresponding, periodical increase in n_{R}. As described above, such an increase in n_{R} may advantageously increase the passivating agents locally, eliminating or reducing a bowing issue.

Referring to FIGS. 4B and 5B, a case of pulsed RF power operation is described. In this case, a pulse train of RF power is provided to generate and sustain a plasma. Accordingly, the radical concentration of the plasma (n_{R}) and the electron temperature (Tₑ) may periodically fluctuate corresponding to the RF power pulsing as illustrated in FIG. 4B. Another pulse train may be applied to generate the additional magnetic field as illustrated in FIG. 5B, resulting in a modulation of the Tₑ and n_{R}. In FIG. 5B, while the frequencies of patterns of Tₑ and n_{R} remain unchanged, a fraction of low Tₑ and that of high n_{R} are prolonged in each cycle due to the additional magnetic field applied. In the illustrated example of FIG. 5B, the RF power pulsing and the magnetic field pulsing are asynchronized (i.e., when the RF power is off, the magnetic field is on, and vice versa), but in other embodiments, various pulsing patterns may be utilized.

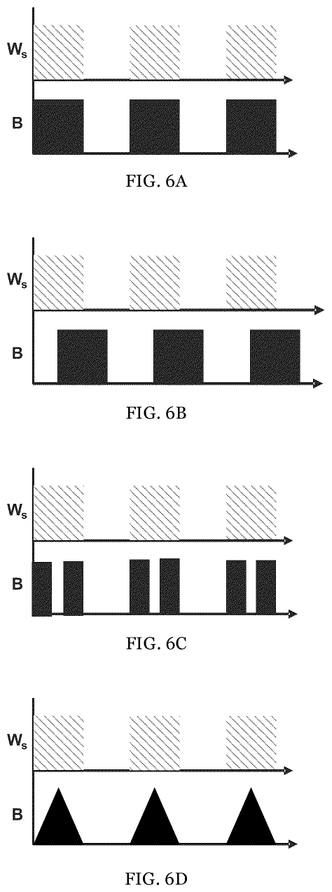

FIGS. 6A-6D illustrate time diagrams for pulsed source power and pulsed additional magnetic field in other embodiments.

FIG. 6A illustrates a case of complete synchronization of RF source power (Wₛ) and the additional magnetic field (B).

FIG. 6B illustrates a case of overlapping of RF source power (Wₛ) and the additional magnetic field (B).

FIG. 6C illustrates a case of multiple magnetic field pulsing per source power cycle. For example, in FIG. 6C, two pulses of the magnetic field (B) may be coupled and synchronized with one pulse of RF source power (Wₛ).

FIG. 6D illustrates a case of triangle wave for the pulsed additional magnetic field (B) in complete synchronization with RF source power (Wₛ). In other embodiments, any suitable wave form (e.g., sinusoidal waves, trapezoidal waves, etc.) may be used.

In the following, the effect of the additional magnetic field on electron distributions of the plasma is described referring to FIGS. 7A-7B, 8A-8B, and 9A-9B.

FIGS. 7A-7B illustrate an example electron distribution in the absence of an additional magnetic field, wherein FIG. 7A illustrates a schematic of electrons of a plasma in a plasma processing chamber, and wherein FIG. 7B illustrates the electron distribution as a function of radial position relative to the substrate.

In FIG. 7A, electrons 700 in a plasma 160 in a plasma processing chamber 110 are unevenly distributed in the absence of any additional magnetic field. The electron concentration (nₑ) is higher at near the center of the substrate and lower at the edge of the substrate as illustrated in FIG. 7B.

FIGS. 8A-8B illustrate an example electron distribution with an additional magnetic field in accordance with one embodiment, wherein FIG. 8A illustrates a schematic of electrons of a plasma in a plasma processing chamber, and wherein FIG. 8B illustrates the electron distribution as a function of radial position relative to the substrate.

As described in prior embodiments, an additional magnetic field 300 may be applied to modulate various plasma species locally. In FIG. 8A, the additional magnetic field 300 is applied in a ring shape that concentrically surrounds the edge of the plasma 160, similar to FIG. 3 in prior embodiments. The cross sectional view of FIG. 3 therefore illustrates two regions of the additional magnetic field 300 near the sidewalls of the plasma processing chamber 110. The additional magnetic field 300 may thus decrease the electron temperature and thereby its mobility near the edge of the plasma 160, resulting in an electron confinement effect. Due to this confinement, the electrons 700 are less likely to escape out of the plasma 160, which leads to more even distribution of the electrons 700 across the substrate 100 as illustrated in FIG. 8B.

FIGS. 9A-9B illustrate an example electron distribution with an additional magnetic field in accordance with another embodiment, wherein FIG. 9A illustrates a schematic of electrons of a plasma in a plasma processing chamber, and wherein FIG. 9B illustrates the electron distribution as a function of radial position relative to the substrate.

In FIG. 9A, an additional magnetic field 300 may be applied above the center of the substrate 100 instead of near the edge of the substrate 100. The additional magnetic field 300 may thus decrease the electron temperature and its mobility near the center of the plasma 160. This may lead to an opposite effect of that in FIG. 8B, and the electron concentration (nₑ) is higher at edge the center of the substrate and lower at the center of the substrate as illustrated in FIG. 9B. Such an embodiment may particularly be advantageous when an increase in passivating agents is desired at the center of the substrate rather than the edge of the substrate.

FIG. 10 illustrates a cross sectional view of an example substrate 100 after a plasma etch with a local bowing issue near the edge region of the substrate. FIG. 11 illustrates a cross sectional view of an example substrate 100 after a plasma etch that uses an additional magnetic field in accordance with various embodiments, where a uniform etch profile across the substrate is enabled with no bowing.

As described above, a non-uniformity of a plasma during a plasma etch process may lead to a local bowing issue. The substrate 100 may comprise an underlying layer 1010 and a hard mask layer 1020. A deposit 1030 may be formed from passivating agents during the plasma etch to passivate the surface. In FIG. 10, two distinct regions of the substrate 100, a central region and an edge region, are illustrated. Due to the non-uniform distribution of passivating agents across the substrate 100, bowed profiles can be seen at the edge of the substrate 100 while the etch profile at the center is vertical with no bowing.

By applying the additional magnetic field to modulate the local density of plasma species such as the passivating agents, this bowing issue may be reduced or eliminated. As illustrated in FIG. 11, a sufficient amount of the deposit 1030 may be formed at the edge of the substrate 100 due to, for example, an increase in the passivating agents near the edge of the substrate 100. As a result, a vertical recess may be realized at the edge of the substrate 100 as well as at the center of the substrate 100.

In various embodiments, the underlying layer 1010 may comprise a polysilicon layer. The polysilicon for the underlying layer 1010 may comprise a doped polysilicon to have desired material properties including electrical properties. The polysilicon layer may be deposited over the substrate 100 using appropriate deposition techniques such as vapor deposition including chemical vapor deposition (CVD), physical vapor deposition (PVD), as well as other plasma processes such as plasma enhanced CVD (PECVD), sputtering, and other processes. In one or more embodiments, the underlying layer 1010 may have a thickness of about 50 nm to about 500 nm.

In various embodiments, the underlying layer 1010 may be patterned by the plasma etch process to form a gate structure or a dummy gate structure for a semiconductor device. Accordingly, the underlying layer 1010 may be patterned into a fin, a pillar, or any suitable shape. The patterning of the underlying layer 1010 may be performed using a plasma dry etch process, for example a reactive ion etching (RIE) process. In one or more embodiments, such a process may be a silicon etch process using a halogen-based chemistry. In one embodiment, an etch gas may comprise a fluorocarbon such as C₄F₈. In various embodiments, the hard mask layer 1020 may be used as an etch mask during the plasma etch process.

The hard mask layer 1020 may comprise silicon oxide in one embodiment. In various embodiments, the hard mask layer 1020 may comprise silicon nitride, silicon carbonitride (SiCN), or silicon oxycarbide (SiOC). In alternate embodiments, the hard mask layer 1020 may comprise titanium nitride. In one or more embodiments, the hard mask layer 1020 may comprise other suitable organic materials such as spin-on carbon hard mask (SOH) materials. Further, the hard mask layer 1020 may be a stacked hard mask comprising, for example, two or more layers using two different materials. In some of such embodiments, the first hard mask of the hard mask layer 1020 may comprise a metal-based layer such as titanium nitride, titanium, tantalum nitride, tantalum, tungsten based compounds, ruthenium based compounds, or aluminum based compounds, and the second hard mask material of the hard mask layer 1020 may comprise a dielectric layer such as silicon oxide, silicon nitride, SiCN, SiOC, silicon oxynitride, or silicon carbide. The hard mask layer 1020 may be deposited using suitable deposition techniques such as vapor deposition including chemical vapor deposition (CVD), physical vapor deposition (PVD), as well as other plasma processes such as plasma enhanced CVD (PECVD), sputtering, and other processes including wet processes. The hard mask layer 1020 may have a thickness of about 5 nm to about 50 nm in various embodiments. In one or more embodiments, an additional layer such as silicon-containing anti-reflective coating films (SiARC) or other ARC films may be formed over the hard mask layer 1020. In further embodiments, a photoresist that may have been used to pattern the hard mask layer 1020 by lithography may be left over the hard mask layer 1020.

FIG. 12 illustrates an example process flow diagrams in accordance with various embodiments.

In FIG. 12, a process flow 1200 starts with loading a substrate that comprises a patterned hard mask layer and an underlying layer in a plasma processing chamber that comprises a RF power source and a set of electromagnets (block 1210). Next, a process gas is flowed into the plasma processing chamber (block 1220), followed by generating a plasma from the process gas in the plasma processing chamber by powering the RF power source (block 1230). Subsequently, a power pulse train is provided to the set of electromagnets to generate a magnetic field in the plasma processing chamber (block 1240). In various embodiments, the magnetic field may be stronger near an edge of the plasma than near a center of the plasma to modulate the local density of plasma species in the plasma processing chamber. The substrate may then be exposed to the plasma in the presence of the magnetic field, enabling etching the underlying layer selectively to the hard mask layer (block 1250).

Example embodiments of the invention are summarized here. Other embodiments can also be understood from the entirety of the specification as well as the claims filed herein.

Example 1. A plasma etching system for a substrate including: a plasma processing chamber; a substrate holder disposed in the plasma processing chamber; a RF power source configured to generate a plasma in the plasma processing chamber; a set of electromagnets configured to apply a magnetic field in the processing chamber, the magnetic field of the set of the electromagnets being independent from a magnetic field generated by the RF power source; and a microprocessor coupled to the RF power source and the set of electromagnets, the microprocessor including a non-volatile memory having a program including instructions to: power the RF power source and generate the plasma in the processing chamber to etch the substrate; and provide a power pulse train to the set of electromagnets and generate the magnetic field that is pulsed, in the plasma processing chamber.

Example 2. The plasma etching system of example 1, where the set of electromagnets is disposed outside of the processing chamber and over an upper wall of the processing chamber.

Example 3. The etching system of one of examples 1 or 2, where the set of electromagnets is arranged concentrically above an edge portion of the substrate holder and is configured to generate the magnetic field that is stronger above the edge portion of the substrate holder than at a central portion of the substrate holder.

Example 4. The plasma etching system of example 1, where the set of the electromagnets is disposed outside of the processing chamber and over a side wall of the processing chamber.

Example 5. The plasma etching system of one of examples 1 to 4, where powering the RF power source includes providing a RF power pulse train to the RF power source.

Example 6. The plasma etching system of one of examples 1 to 5, where the power pulse train and the RF power pulse train are synchronized.

Example 7. The plasma etching system of one of examples 1 to 5, where the power pulse train and the RF power pulse train are asynchronous.

Example 8. A method of processing a substrate that includes: loading the substrate in a plasma processing chamber, the substrate including a patterned hard mask layer and an underlying layer, the processing chamber including a RF power source and a set of electromagnets; flowing a process gas into the plasma processing chamber; generating a plasma from the process gas in the plasma processing chamber by powering the RF power source; providing a power pulse train to the set of electromagnets to generate a magnetic field in the plasma processing chamber, the magnetic field being stronger near an edge of the plasma than near a center of the plasma; and while providing the power pulse train to the set of electromagnets, exposing the substrate to the plasma and etching the underlying layer selectively to the hard mask layer.

Example 9. The method of example 8, where the process gas includes fluorocarbon and the underlying layer includes silicon.

Example 10. The method of one of examples 8 or 9, where powering the RF power source includes providing a RF power pulse train to the RF power source.

Example 11. The method of one of examples 8 to 10, where the power pulse train and the RF power pulse train are synchronized.

Example 12. The method of one of examples 8 to 11, where the plasma includes etchant species and passivant species, the method further including correcting radial concentration gradients of the etchant species and the passivant species by tuning an magnitude of the power pulse train to the set of electromagnets to locally adjust the magnetic field.

Example 13. The method of one of examples 8 to 12, where the set of electromagnets is disposed outside of the processing chamber and over an upper wall of the processing chamber.

Example 14. The method of one of examples 8 to 13, where the substrate is loaded over a substrate holder, and where the set of electromagnets is arranged concentrically above an edge portion of the substrate holder and is configured to generate the magnetic field that is stronger above the edge portion of the substrate holder than at a central portion of the substrate holder.

Example 15. The method of one of examples 8 to 12, where the set of the electromagnets is disposed outside of the processing chamber and over a side wall of the processing chamber.

Example 16. A method of processing a substrate that includes: loading the substrate in a plasma processing chamber, the substrate including a patterned hard mask layer and an underlying layer, the processing chamber including a RF power source and a set of electromagnets; flowing a process gas into the plasma processing chamber; generating a plasma from the process gas in the plasma processing chamber by powering the RF power source; exposing the substrate to the plasma and etching the underlying layer selectively to the hard mask layer, where an etch rate is greater at near an edge region of the substrate than at a central region of the substrate; and providing a power pulse train to the set of electromagnets to generate a magnetic field in the plasma processing chamber, the magnetic field reducing the difference in the etch rate between near the edge region and the central region.

Example 17. The method of example 16, where powering the RF power source includes providing a RF power pulse train to the RF power source, the RF power pulse train including an on-phase and an off-phase.

Example 18. The method of one of examples 16 or 17, where the power pulse train and the RF power pulse train are overlapped.

Example 19. The method of one of examples 16 to 18, where the magnetic field is present during the on-phase of the RF power pulse train.

Example 20. The method of one of examples 16 to 19, where the magnetic field is present during the off-phase of the RF power pulse train.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A plasma etching system for a substrate comprising:
a plasma processing chamber;
a substrate holder disposed in the plasma processing chamber;
a RF power source configured to generate a plasma in the plasma processing chamber;
a set of electromagnets configured to apply a magnetic field in the processing chamber, the magnetic field of the set of the electromagnets being independent from a magnetic field generated by the RF power source; and
a microprocessor coupled to the RF power source and the set of electromagnets, the microprocessor comprising a non-volatile memory having a program comprising instructions to:
power the RF power source and generate the plasma in the processing chamber to etch the substrate; and
provide a power pulse train to the set of electromagnets and generate the magnetic field that is pulsed, in the plasma processing chamber.

2. The plasma etching system of claim 1, wherein the set of electromagnets is disposed outside of the processing chamber and over an upper wall of the processing chamber.

3. The etching system of claim 2, wherein the set of electromagnets is arranged concentrically above an edge portion of the substrate holder and is configured to generate the magnetic field that is stronger above the edge portion of the substrate holder than at a central portion of the substrate holder.

4. The plasma etching system of claim 1, wherein the set of the electromagnets is disposed outside of the processing chamber and over a side wall of the processing chamber.

5. The plasma etching system of claim 1, wherein powering the RF power source comprises providing a RF power pulse train to the RF power source.

6. The plasma etching system of claim 5, wherein the power pulse train and the RF power pulse train are synchronized.

7. The plasma etching system of claim 5, wherein the power pulse train and the RF power pulse train are asynchronous.

8. A method of processing a substrate, the method comprising:
loading the substrate in a plasma processing chamber, the substrate comprising a patterned hard mask layer and an underlying layer, the processing chamber comprising a RF power source and a set of electromagnets;
flowing a process gas into the plasma processing chamber;
generating a plasma from the process gas in the plasma processing chamber by powering the RF power source;
providing a power pulse train to the set of electromagnets to generate a magnetic field in the plasma processing chamber, the magnetic field being stronger near an edge of the plasma than near a center of the plasma; and
while providing the power pulse train to the set of electromagnets, exposing the substrate to the plasma and etching the underlying layer selectively to the hard mask layer.

9. The method of claim 8, wherein the process gas comprises fluorocarbon and the underlying layer comprises silicon.

10. The method of claim 8, wherein powering the RF power source comprises providing a RF power pulse train to the RF power source.

11. The method of claim 10, wherein the power pulse train and the RF power pulse train are synchronized.

12. The method of claim 8, wherein the plasma comprises etchant species and passivant species, the method further comprising correcting radial concentration gradients of the etchant species and the passivant species by tuning an magnitude of the power pulse train to the set of electromagnets to locally adjust the magnetic field.

13. The method of claim 8, wherein the set of electromagnets is disposed outside of the processing chamber and over an upper wall of the processing chamber.

14. The method of claim 13, wherein the substrate is loaded over a substrate holder, and wherein the set of electromagnets is arranged concentrically above an edge portion of the substrate holder and is configured to generate the magnetic field that is stronger above the edge portion of the substrate holder than at a central portion of the substrate holder.

15. The method of claim 8, wherein the set of the electromagnets is disposed outside of the processing chamber and over a side wall of the processing chamber.

16. A method of processing a substrate, the method comprising:
loading the substrate in a plasma processing chamber, the substrate comprising a patterned hard mask layer and an underlying layer, the processing chamber comprising a RF power source and a set of electromagnets;
flowing a process gas into the plasma processing chamber;
generating a plasma from the process gas in the plasma processing chamber by powering the RF power source;
exposing the substrate to the plasma and etching the underlying layer selectively to the hard mask layer, wherein an etch rate is greater at near an edge region of the substrate than at a central region of the substrate; and
providing a power pulse train to the set of electromagnets to generate a magnetic field in the plasma processing chamber, the magnetic field reducing the difference in the etch rate between near the edge region and the central region.

17. The method of claim 16, wherein powering the RF power source comprises providing a RF power pulse train to the RF power source, the RF power pulse train comprising an on-phase and an off-phase.

18. The method of claim 17, wherein the power pulse train and the RF power pulse train are overlapped.

19. The method of claim 17, wherein the magnetic field is present during the on-phase of the RF power pulse train.

20. The method of claim 17, wherein the magnetic field is present during the off-phase of the RF power pulse train.
